(19) United States
(12) Patent Application Publication
(10) Pub. No.: US 2011/0242751 A1
(43) Pub. Date: Oct. 6, 2011

(54) FOLDABLE PORTABLE TERMINAL APPARATUS

(75) Inventors: Yasutoki Manda, Kanagawa (JP); Hidehiro Yanagibashi, Kanagawa (JP); Haruo Hayakawa, Kanagawa (JP)

(73) Assignee: PANASONIC CORPORATION, Osaka (JP)

(21) Appl. No.: 12/996,278

(22) PCT Filed: Feb. 10, 2009
(86) PCT No.: PCT/JP2009/000542

§ 371 Date: Jun. 17, 2011

(30) Foreign Application Priority Data
Jun. 3, 2008 (JP) 2008-145315

(51) Int. Cl. G06F 1/16; H05K 5/00

(52) U.S. Cl. 361/679.27; 361/679.01

(57) ABSTRACT

A foldable portable terminal apparatus includes: a first casing including an operation portion, and a second casing including a display portion, which are connected through a connection portion so as to allow the second casing to open and close with respect to the first casing in a first direction and a second direction different from the first direction. The portable terminal apparatus includes a slide sheet printed with a character or symbol for operation purpose. The slide sheet slides in association with opening and closing actions in the first direction and has a hole formed along a sliding direction thereof.

### TECHNICAL FIELD

The present invention relates to a folding portable terminal apparatus in which two casings are connected so as to be opened and closed in a first direction and a second direction.

### BACKGROUND ART

As a usage of a foldable mobile telephone in which two casings are connected so as to overlap, a user generally holds a first casing including an operation portion such as a ten-key pad in user's hand and views a second casing including a display portion by setting the foldable mobile telephone in a state in which the foldable mobile telephone is opened around a connection portion.

Recently, a mobile telephone capable of receiving and displaying a television broadcast is put to practical use and starts to become widespread. In order to view a landscape television broadcast screen, it is known to be preferable to rotate a display portion in a second direction. In view of this, there is proposed a mechanism for switching a direction of the display portion from a first direction to the second direction by mechanically rotating the second casing including the display portion in the second direction around a rotation shaft provided in an end portion of the second casing (for example, see Patent Document 1).

FIGS. 18 and 19 show one example of the foldable mobile telephone proposed conventionally. A mobile telephone 60 of FIG. 18 includes three casings, i.e., a first casing 61 including an operation portion 71, a second casing 62 including a display portion 72, and a connection portion 63. The connection portion 63 is rotatably supported in a direction of arrow A by a first rotation shaft 61a provided in the first casing 61. By rotating the connection portion 63 in the direction of arrow A, the second casing 62 can be opened in a first direction with respect to the first casing 61. A second rotation shaft 63a is provided in the connection portion 63 and rotatably supports the second casing 62. Consequently, the mobile telephone 60 can be used in a form of opening the display portion 72 of the second casing 62 in a second direction finally as shown in FIG. 19.

In this case, when the second casing 62 is opened in the second direction and the display portion 72 is set in a landscape state, it is convenient to change arrangement and orientation of the operation portion 71 such as a ten-key pad to arrangement and orientation for viewing a television broadcast. As a method for that purpose, it may be considered that the operation portion is configured by a touch panel with a liquid crystal display and to change key arrangement and orientation of the liquid crystal display every time orientation of the display portion 72 changes. However, it may not be appropriate to maintain the liquid crystal display and backlight in ON state while the television broadcast is viewed. Therefore, after the liquid crystal display is once turned off, the channel can be selected as necessary by touching the touch panel so as to again turn on the liquid crystal display. Further, it is considered to make no display in an optimum character input direction when open/close operation of the casing is performed in a power-off state (for example, see Patent Document 2).

Patent Document 1: JP-A-2006-22899

Patent Document 2: JP-A-2001-296958

### DISCLOSURE OF THE INVENTION

### Problem to be Solved by the Invention

A first problem of the invention is, in a foldable portable terminal apparatus, e.g., a mobile telephone, a game machine or PDA (Personal Digital Assistants) having a television broadcast receiving function, including a connection portion containing two rotation shafts so as to open and close the apparatus in a first direction and a second direction, to change characters and symbols for operation purpose such as a ten-key pad according to orientation of a display device of liquid crystal etc. when a second casing is opened from a folded state by rotating the rotation shaft of the connection portion.

A second problem is to provide a user-friendly portable terminal apparatus capable of switching the characters and symbols for the operation purpose such as the ten-key pad according to the orientation of the display device of liquid crystal etc. even when a power source is not turned on.

A third problem is to allow a change according to the orientation of the display device by opening or closing the second casing with respect to a first casing even when a user does not intentionally perform an operation for the change.

A fourth problem is to allow a ten-key pad, four-way directional pad, etc. to be pushed easily so as to improve operability at the push.

### Means for Solving the Problem

According to the invention, a foldable portable terminal apparatus comprises a first casing including an operation portion, and a second casing including a display portion, which are connected through a connection portion so as to allow the second casing to open and close with respect to the first casing in a first direction and a second direction different from the first direction, wherein said portable terminal apparatus comprises a slide sheet printed with a character or symbol for operation purpose, and wherein the slide sheet slides in association with opening and closing actions in the first direction and has a hole formed along a sliding direction thereof. Further, according to the invention, a foldable portable terminal apparatus comprises a first casing including an operation portion and a second casing including a display portion, which are connected through a connection portion so as to allow the second casing to open and close with respect to the first casing in a first direction and a second direction different from the first direction, wherein said portable terminal apparatus comprises a slide sheet printed with a character or symbol for operation purpose, and wherein the slide sheet slides in association with opening and closing actions in the first direction and has a hole formed along the first direction.

Further, according to the invention, a foldable portable terminal apparatus comprises a first casing including an operation portion, and a second casing including a display portion, which are connected through a connection portion so as to allow the second casing to open and close with respect to the first casing in a first direction and a second direction different from the first direction, wherein said portable terminal apparatus comprises a slide sheet printed with a character or symbol for operating a plurality of direction buttons, and wherein the slide sheet slides in association with opening and closing actions in the first direction, and has first and second holes formed along a sliding direction thereof and a third hole connecting the first hole and the second hole. Moreover, according to the invention, a foldable portable terminal apparatus comprises a first casing including an operation portion, and a second casing including a display portion, which are connected through a connection portion so as to allow the second casing to open and close with respect to the first casing in a first direction and a second direction different from the first direction, wherein said portable terminal apparatus comprises a slide sheet printed with a character or symbol for operating a plurality of direction buttons, and wherein the slide sheet slides in association with opening and closing actions in the first direction, and has first and second holes formed along the first direction and a third hole connecting the first hole and the second hole.

According to the invention, a slide sheet is used in an operation portion of a foldable portable terminal apparatus that comprises a first casing including the operation portion, and a second casing including a display portion, which are connected through a connection portion so as to allow the second casing to open and close with respect to the first casing in a first direction and a second direction different from the first direction, wherein said slide sheet has a print of character or symbol for operation purpose, slides in association with opening and closing actions in the first direction, and has a hole formed along a sliding direction thereof. Further, according to the invention, a slide sheet is used in an operation portion of a foldable portable terminal apparatus that comprises a first casing including the operation portion, and a second casing including a display portion, which are connected through a connection portion so as to allow the second casing to open and close with respect to the first casing in a first direction and a second direction different from the first direction, wherein said slide sheet has a print of a character or symbol for operation purpose, slides in association with opening and closing actions in the first direction and has a hole formed along the first direction.

Further, a slide sheet of the present invention is used in a region of a plurality of direction buttons of a foldable portable terminal apparatus that comprises a first casing including an operation portion and a second casing including a display portion, which are connected through a connection portion so as to allow the second casing to open and close with respect to the first casing in a first direction and a second direction different from the first direction, wherein said slide sheet has a print of character or symbol for operating the plurality of direction buttons, slides in association with opening and closing actions in the first direction, and has first and second holes formed along a sliding direction thereof and a third hole connecting the first hole to the second hole. Moreover, a slide sheet of the present invention is used in a region of a plurality of direction buttons of a foldable portable terminal apparatus that comprises a first casing including an operation portion and a second casing having a display portion, which are connected through a connection portion so as to allow the second casing to open and close with respect to the first casing in a first direction and a second direction different from the first direction, wherein said slide sheet has a print of a character or symbols for operating the plurality of direction buttons, slides in association with opening and closing actions in the first direction, and has first and second holes formed along the first direction and a third hole connecting the first hole to the second hole.

According to the invention, a foldable portable terminal apparatus comprises a first casing including an operation portion and a second casing including a display portion, which are connected through a connection portion so as to allow the second casing to open and close with respect to the first casing in a first direction and a second direction different from the first direction, wherein said portable terminal apparatus comprises a slide sheet printed with a character or symbol for operation purpose, and wherein the slide sheet slides in association with opening and closing actions in the first direction and comprises a protrusion in a direction perpendicular to a sliding direction such that when sliding, the slide sheet is positionally regulated by the protrusion in the direction perpendicular to the sliding direction. Further, according to the invention, a foldable portable terminal apparatus comprises a first casing including an operation portion and a second casing including a display portion, which are connected through a connection portion so as to allow the second casing to open and close with respect to the first casing in a first direction and a second direction different from the first direction, wherein said portable terminal apparatus comprises a slide sheet printed with a character or symbol for operation purpose, and wherein the slide sheet slides in association with opening and closing actions in the first direction and comprises a protrusion in the second direction such that when sliding, the slide sheet is positionally regulated by the protrusion in the second direction.

According to the present invention, a slide sheet of the present invention is used in an operation portion of a foldable portable terminal apparatus that comprises a first casing including the operation portion and a second casing including a display portion, which are connected through a connection portion so as to allow the second casing to open and close with respect to the first casing in a first direction and a second direction different from the first direction, wherein said slide sheet has a print of a character or symbol for operation purpose, slides in association with opening and closing actions in the first direction, and comprises a protrusion in a direction perpendicular to a sliding direction thereof such that when sliding, the slide sheet is positionally regulated by the protrusion in the direction perpendicular to the sliding direction. Further, according to the invention, a slide sheet is used in an operation portion of a foldable portable terminal apparatus that comprises a first casing including the operation portion and a second casing including a display portion, which are connected through a connection portion so as to allow the second casing to open and close with respect to the first casing in a first direction and a second direction different from the first direction, wherein said slide sheet has a print of a character or symbol for operation purpose, slides in association with opening and closing actions in the first direction, and comprises a protrusion in the second direction such that when sliding, the slide sheet is positionally regulated by the protrusion in the second direction.

A cam follower member (hereinafter abbreviated as a “follower member”) serves as a connection member arrange so as to interlock with a rotation of a first rotation shaft. Further, the connection portion includes the first rotation shaft that allows the second casing to rotate in the first direction with respect to the first casing and a second rotation shaft that allows the second casing to rotate with respect to the first casing in the second direction perpendicular to the first direction.

The first rotation shaft further includes a protrusion fixed thereto and configured to cause the follower member to slide. When the connection portion is rotated in the first direction with respect to the first casing, the first rotation shaft fixed to the connection portion and the protrusion fixed to the first rotation shaft are rotated, and the follower member is actuated by motions of the protrusions, whereby the slide sheet slides. The operation portion of the first casing is arranged so as to enable selective viewing of a character array conforming to a direction of the second casing through a display window provided on a key top sheet of the operation portion, in accordance with rotation of the second casing including the display portion in the first or second direction and with respect to the first casing.

Specifically, either one of groups of characters printed on the slide sheet so as to be displayed in two different directions, respectively, is displayed on the display window of the first casing between when the connection portion is rotated with respect to the first casing and in the first direction along with the second casing and when the second casing is rotated in the second direction with respect to the first casing.

By rotating the connection portion and the second casing with respect to the first casing by the configuration, the orientation of button layout of the operation portion and the orientation of the display can be switched appropriately with respect to the display portion of the second casing.

In the present invention, there are further provided stopper means fixed to an inside of the first casing and an elastic member which connects the stopper means and the cam follower member. When the slide sheet moves for a predetermined distance, the cam follower member contacts the stopper means so as to regulate a sliding motion.

A slit formed in a portion of the slide sheet where functions of the respective buttons are not printed, whereby the slide sheet is made more deformable. As a result, it is easier to press ten digit buttons, or the like, thereby enhancing operability during pressing operation.

In a foldable portable terminal apparatus including a four-way directional pad, a substantially H-shaped slit is formed at a position corresponding to a center of a print of functions of respective buttons located around the four-way directional pad of the slide sheet in a distributed manner. As a result, it is possible to easily press the four-way directional pad and an enter key located at a center of the four-way directional pad, thereby enhancing operability during pressing action.

The slit of the slide sheet is not formed in a sequence of characters located on an end portion of the slide sheet opposite to a side thereof connected to the cam follower (a fulcrum) in a longer direction thereof, whereby rigidity of a portion of the slide sheet most distant from the fulcrum is assured.

Moreover, protrusions are formed on an inside of the frame portion in a shorter direction thereof and at both ends of the slide sheet in the shorter direction thereof, and the protrusions are contact with one another, thereby preventing a horizontal positional displacement of the slide sheet at the sliding motion.

### Advantages of the Invention

According to the present invention, in a foldable portable terminal apparatus, e.g., a mobile telephone, a game machine, or a PDA having a television broadcast receiving function, including two rotation shafts and configured to open and close in a first direction and a second direction, the character or symbol for operation purpose, such as the ten-key pad can be changed in conformance to an orientation of a display portion of a liquid crystal, etc., by rotating the rotation shafts of the connection portion from a state in which the second casing is folded,

Since switching is performed mechanically, the character or symbol for operation purpose such as ten-key pad can be switched in conformance to an orientation of the display portion of a liquid crystal, etc., provided in the second casing by rotating a display surface of the second casing the first direction or the second direction with respect to the first casing when a power supply of the portable terminal apparatus is not turned on.

The orientation of the character or symbol for operation purpose is switched by only the opening and closing actions, which can provide an advantage the user does not need to perform operation purposely.

Further, the slits are formed in the slide sheet, which allows the ten-key pad, the four directional keys, etc., to be pressed easily, whereby operability at the pressing operation is enhanced.

Further, a sealed structure is formed by the key top sheet, the frame portion, and the pusher sheet. Accordingly, even when the slit is formed in the slide sheet, it is possible to provide the structure with enhanced dust proof and water proof functions.

According to the invention, in addition to the configuration described above, the radio communication means and the television broadcast receiving means are further provided. The slide sheet has a character for wireless communication and a character for receiving a television broadcast. When the connection portion along with the second casing is opened in the first direction with respect to the first casing, the character for wireless communication is displayed. When the second casing is opened in the second direction with respect to the first casing, the character for receiving a television broadcast is displayed.

By this configuration, when the casing is opened in the first direction, the character for wireless communication can be displayed, and when the casing is opened in the second direction, the character for receiving a television broadcast can be displayed.

### BRIEF DESCRIPTION OF THE DRAWINGS

FIG. 1 is a perspective view showing a state in which a casing of a mobile telephone according to a first embodiment of the present invention is opened in a first direction.

FIG. 2 is a perspective view showing a state in which the casing of the mobile telephone according to the first embodiment of the present invention is opened in a second direction.

FIG. 3 is an exploded perspective view of a main part of an operation portion of the mobile telephone according to the first embodiment of the present invention.

FIG. 4 is a perspective view showing a structure of a portion related to a slide sheet of the first embodiment of the present invention.

FIG. 5 is a partial sectional view showing the structure of the portion related to the slide sheet of the first embodiment of the present invention.

FIG. 6 is a perspective view showing the structure of another portion related to the slide sheet of the first embodiment of the present invention.

FIG. 7(a) is a partial sectional view showing a state in which the casing of the mobile telephone of the first embodiment of the present invention is opened in the first direction, and FIG. 7(b) is a partial sectional view showing a state in which the casing of the mobile telephone of the first embodiment of the present invention is opened in the first direction.

FIG. 8 is a plan view showing a state in which the casing of the mobile telephone of the first embodiment of the present invention is opened in the first direction.

FIG. 9 is a partial sectional view of the mobile telephone of the first embodiment of the present invention when the mobile telephone is closed.

FIG. 10(a) It is a partial sectional view showing the state in which the casing of the mobile telephone of the first embodiment of the present invention is opened in the second direction, and FIG. 10(b) is a partial sectional view showing the state in which the casing of the mobile telephone of the first embodiment of the present invention is opened in the second direction.

FIG. 11(a) is a partial sectional view of the operation portion of the mobile telephone of the first embodiment of the present invention, FIG. 11(b) is a partial sectional view of the operation portion of the mobile telephone of the first embodiment of the present invention, and FIG. 11(c) is a partial sectional view of an operation portion of a related art mobile telephone compared with the first embodiment of the present invention.

FIG. 12(a) is a plan view of the operation portion of the mobile telephone of the first embodiment of the present invention, and FIG. 12(b) is a plan view of the operation portion of the mobile telephone of the first embodiment of the present invention.

FIG. 13(a) is a perspective view of another slide sheet of the mobile telephone of the first embodiment of the present invention, and FIG. 13(b) is a perspective view of the another slide sheet of the mobile telephone of the first embodiment of the present invention.

FIG. 14 is a perspective view of another slide sheet of the mobile telephone of the first embodiment of the present invention.

FIG. 15 is a perspective view showing a structure of the portion related to the slide sheet of the first embodiment of the present invention.

FIG. 16 is a partial sectional view showing the structure of the portion related to the slide sheet of the first embodiment of the present invention.

FIG. 17(a) is a partial sectional view showing a state in which the casing of the mobile telephone of the first embodiment of the present invention is opened in the first direction, FIG. 17(b) is a partial sectional view showing that the casing of the mobile telephone of the first embodiment of the present invention is opened in the first direction, and FIG. 17(c) is a partial sectional view showing the closed casing of the mobile telephone of the first embodiment of the present invention.

FIG. 18 is a perspective view showing a state in which a second casing of the mobile telephone of the related art is opened in the first direction.

FIG. 19 is a perspective view showing a state in which the second casing of the mobile telephone of the related art is opened in the second direction.

### DESCRIPTION OF REFERENCE SIGNS

1 FIRST CASING
2 SECOND CASING
3 CONNECTION PORTION
4 KEY CIRCUIT BOARD
5 DIAPHRAGM
6 FRAME PORTION
7 FOLLOWER MEMBER
8 TORSION COIL SPRING HOLDING PORTION
9 FIRST ROTATION SHAFT
10 SECOND ROTATION SHAFT
11 TORSION COIL SPRING
12 PROTRUSION
13 SLIDE SHEET
16 KEY TOP SHEET
19 PUSHER SHEET
51 OPERATION PORTION
80, 81 SLIT

### BEST MODE FOR CARRYING OUT THE INVENTION

### First Embodiment

In a first embodiment of the present invention, the problems is solved by using a state of a connection portion serving as a third casing and configured to connect a first casing and a second casing, In which the connection portion is opened or remains closed with respect to the first casing including an operation portion depending on whether the second casing is opened with respect to the first casing in a first direction (first direction of the casing) or a second direction (second direction of the casing).

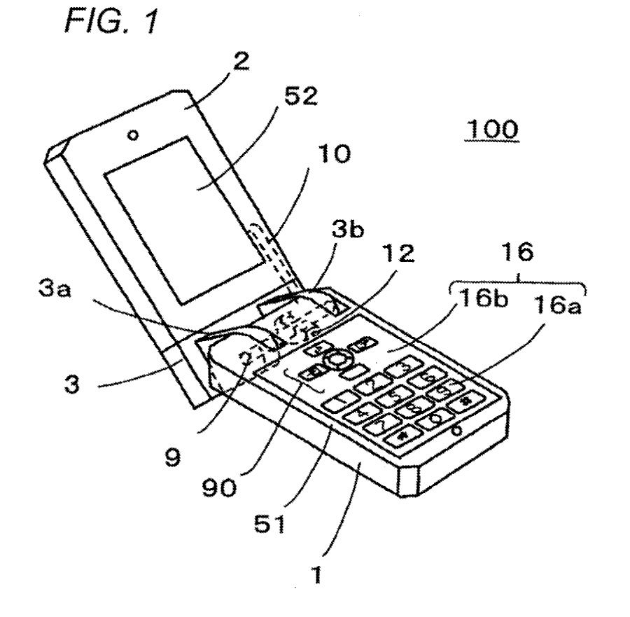

FIG. 1 is a perspective view showing a state in which a second casing 2 of a foldable mobile telephone 100 of the first embodiment of the present invention is opened in a first direction. A first casing 1 including an operation portion 51 rotatably supports a first rotation shaft 9 by a bearing portion (not shown). The first rotation shaft 9 is fixed integrally to a connection portion 3 by shaft holding portions 3a and 3b. A protrusion 12 shown by a broken line is fixed to the first rotation shaft 9. Therefore, the connection portion 3, the first rotation shaft 9, and the protrusion 12 rotate as an integrated component. In on corner of the connection portion 3, a second rotation shaft 10 shown by a broken line is provided so as to extend perpendicular to the first rotation shaft 9, and the second casing 2 is rotatably mounted to the second rotation shaft 10. The second casing 2 is provided with a display portion 52.

The operation portion 51 disposed on an upper surface of the first casing 1 includes a key top sheet 16. The key top sheet 16 includes a transparent display window 16a and an opaque area 16b, such that characters and symbols for operation purpose become visible through the display window 16a.

As described above, in the foldable mobile telephone 100, when the second casing 2 is opened in the first direction with respect to the first casing 1, ten-key numeric characters of the operation portion 51 are displayed by ten-key arrangement for telephone specified by standards are oriented in the first direction as a vertical direction thereof, so as to be used as the telephone.

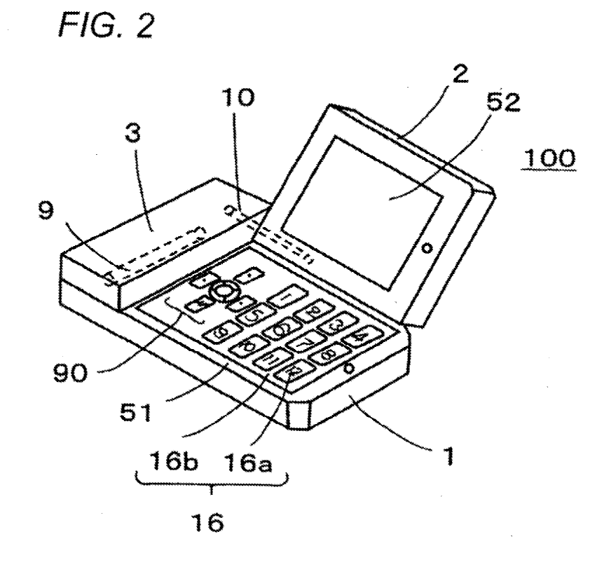

FIG. 2 shows is a perspective view showing a state in which the second casing 2 of the foldable mobile telephone 100 of the first embodiment of the present invention is ,opened in a second direction. Arrangement of each portion is the same as that shown in FIG. 1, but the second casing 2 is rotated around the second rotation shaft 10 from a closed state, and the second casing 2 is opened in the second direction with respect to the first casing 1. In addition, the connection portion 3 is closed with respect to the first casing 1. The ten-key numeric characters of the operation portion 51 are arranged so as to be easy to operate the telephone as a television broadcast receiver. Specifically, the characters “1,” “2, “3,” and “4” are arranged in a first row from the left; the characters “5,” “6,” “7,” and “8” are arranged in a second row from the left; and the characters “9,” “10,” “11,” and “12” are arranged in a third row from the left. The digits are also displayed in a direction while the second direction of the casing is taken as the vertical direction.

In the foldable mobile telephone 100, printed characters of the operation portion 51 are arranged so as to become visible in an orientation appropriate for the direction of a display of a liquid crystal display portion in each of cases where the second casing 2 is opened in the first direction with respect to the first casing 1 and where the second casing 2 is opened in the second direction with respect to the first casing 1. A configuration of the operation portion is hereunder described.

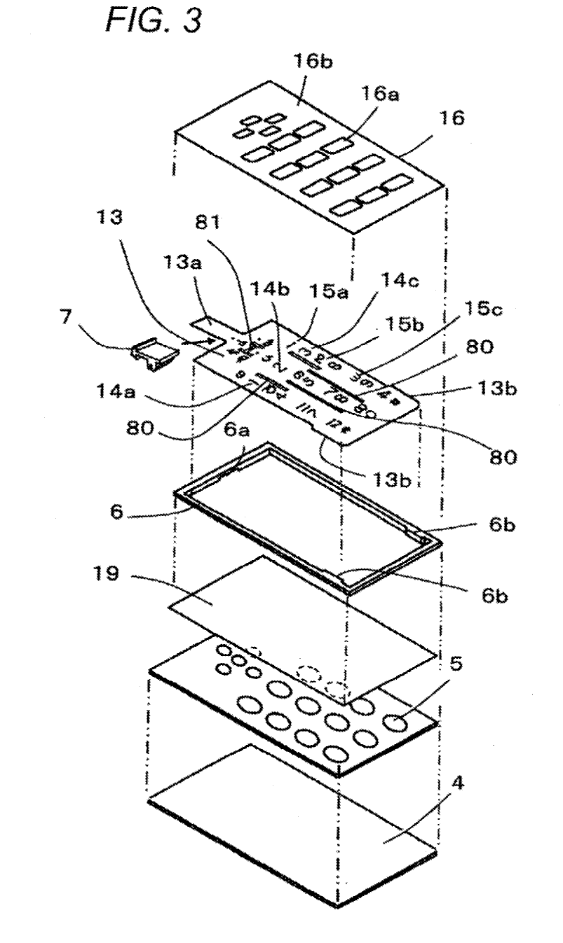

FIG. 3 is an exploded perspective view of a main part of the operation portion 51. As shown in FIG. 3, characters and symbols for operation purpose to be assigned to respective numeric buttons, or the like, are printed on a surface of a slide sheet 13. Specifically, numeric characters for ten-key pad (e.g., 14a, 14b, and 14c) of “1,” “2,” “3,” . . . for telephone purpose are printed in sequence.

Further, numeric characters for television channels (e.g., 15a, 15b, 15c) are printed and arranged alternately with the numeric characters for ten-key pad for phone purpose.

The orientation of the numeric characters (a first print group) for ten-key pad for telephone use is set in the first direction of the second casing 2 that is taken as the vertical direction thereof, and the orientation of the numeric characters (a second print group) for TV channels is set at an angle changed 90° so as to be oriented in the second direction. Slits 80 are formed in a region of the slide sheet 13 where functions of the respective buttons are not printed. A substantially H-shaped slit 81 is formed in a vicinity of a position corresponding to a center of printed functions of respective buttons arranged, in a distributed manner, around a four-way directional pad.

The slide sheet 13 is made of a plastic sheet which is thin but has rigidity enough to prevent buckling. As shown in FIG. 3, a follower mounting portion 13a is formed in a protrusion shape in one end.

The slits 80 and the substantially H-shaped slit 81 provide an effect of making the slide sheet 13 easy to become deformed when the slide sheet is pressed from above. However, the slits 80 are formed narrowly elongated in a direction of sliding movement of the slide sheet 13 as will be described later. Therefore, even when sliding, the slide sheet 13 does not become deformed at the regions where slits 80 are provided. Longitudinal holes on both sides of the substantially H-shaped slit 81 are also formed so as to become narrowly elongated along the direction of sliding movement of the slide sheet. Likewise, the slide sheet 13 does not become bent by the substantially H-shaped slit 81 even when sliding.

A frame portion 6 is provided in the periphery of the slide sheet 13 shown in FIG. 3, and a pusher sheet 19 is provided on a back surface side of the side sheet 13 (a surface opposite to a printed surface). The frame portion 6 is provided so as to surround the periphery of the slide sheet in order to regulate movement of the slide sheet 13. A step portion 6a is provided in a lower surface (a back) of the frame portion 6, which reduces the thickness of the frame portion 6 such that the follower mounting portion 13a of the slide sheet 13 can pass through the step portion 6a. The pusher sheet 19 is adhered and fixed to the lower surface of the frame portion 6 in order to improve the click feel of the key.

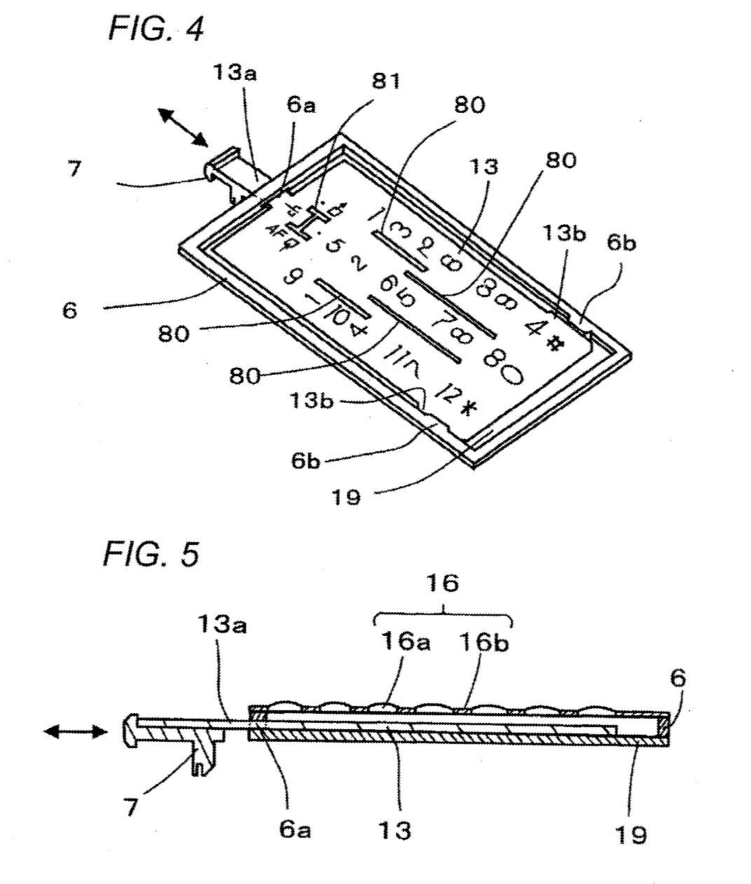

The slide sheet 13 is placed on the pusher sheet 19 while the pusher sheet 19 is adhered and fixed to the lower surface of the frame portion 6. The follower mounting portion 13a formed at one end of the slide sheet 13 is caused to pass through a space between the step portion 6a of the frame portion and the pusher sheet 19, and a follower member 7 is fixed to the follower mounting portion 13a. FIG. 4 shows a perspective view showing this state, and FIG. 5 shows a cross sectional view when the key top sheet 16 described later is adhered to an upper surface of the frame portion 6.

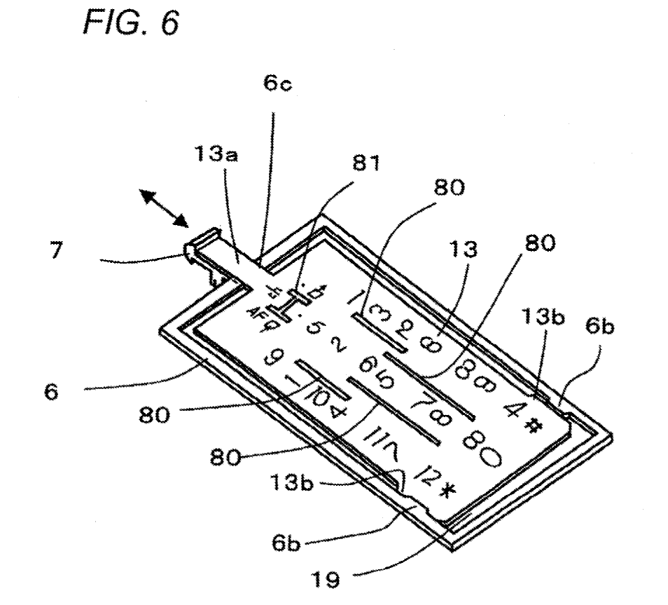

The step portion 6a is not always necessarily provided in the frame portion 6. As shown in FIG. 6, a region corresponding to the step portion 6a may be taken as an opening 6c. So long as the opening 6c allows the follower mounting portion 13a of the slide sheet 13 to slide, the thickness of the frame portion 6 can be reduced.

Returning back to FIG. 3, the key top sheet 16 made of a plastic material, etc., is laminated on a front surface of the slide sheet 13. In the key top sheet 16, the display window 16a is made to a size equal to a print of one group of characters and at a print interval of one group of characters such that only a print of the first group of characters or a print of the second group of characters of the slide sheet 13 becomes visible. The remaining area 16b is made opaque. The key top sheet 16 is adhered and fixed to an upper surface of the frame portion 6. The slide sheet 13 slides in a space sealed by the key top sheet 16, the frame portion 6, and the pusher sheet 19.

As described above, in the present invention, the slide sheet 13 is moved in a sliding manner in the sealed space, thereby preventing penetration of fibers or dust into the sealed space from the outside.

Fibers or dust is thereby prevented from being piled on the first group of characters or the second group of characters printed on the slide sheet 13. In general, forming slits in the key top sheet and the pusher sheet can reduce resistance against a flexure caused by pressing action, but may be difficult to prevent penetration of fibers and dust is not. However, according to the present invention, the slits are formed in the slide sheet rather than in the pusher sheet. Further, a sealed structure is made by combination of the pusher sheet, the key top sheet, and the frame portion, thereby preventing deterioration of appearance of a printed character and therearound caused by penetration of fibers and dust onto the slide sheet.

When the first rotation shaft 9 reaches a predetermined angle or more, the follower member 7 moves so as to follow the protrusion 12 mounted to the first rotation shaft 9 described later. Therefore, the slide sheet 13 connected to the follower member 7 slides, in the sealed space formed by the frame portion 6, the pusher sheet 19, and the key top sheet 16, while following a rotation of the first rotation shaft 9.

In FIG. 3, diaphragms 5 and a key circuit board 4 are provided below the frame portion 6 and the pusher sheet 19. The number of diaphragms 5 is smaller than the number of characters and numeric characters printed on the slide sheet 13. When the diaphragm 5 is pressed from above, the center portion of the diaphragm is dented, and a contact point provided at a position overlapping the center portion contacts and is electrically connected with a key contact circuit on the key circuit board 4, whereby the press is detect.

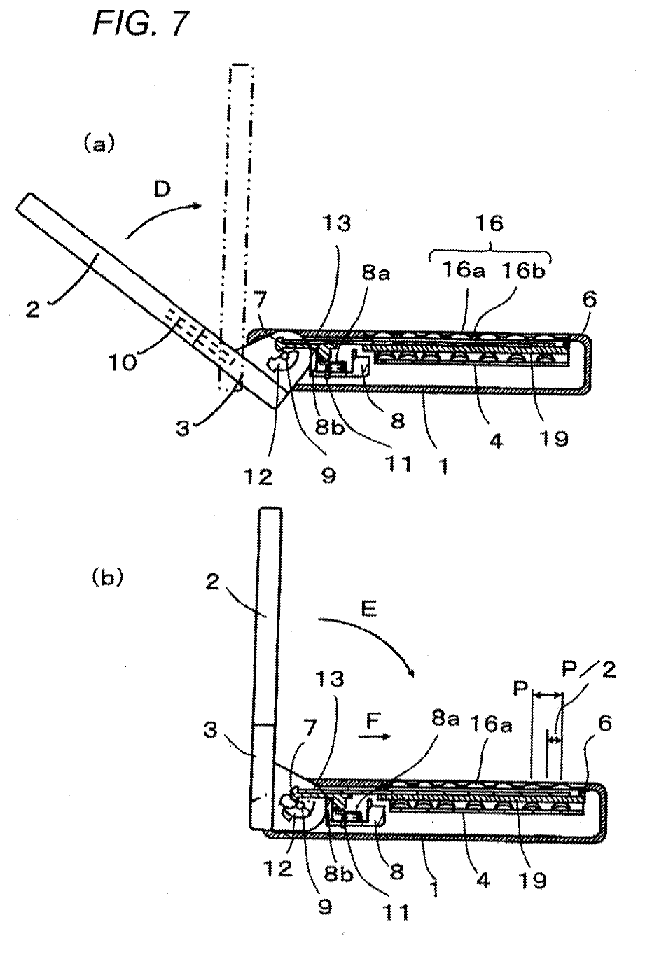

FIGS. 7(a) and (b) are partial cross sectional views showing that the second casing 2 of the foldable mobile telephone 100 of the first embodiment of the present invention is opened in the first direction and that the second casing is closed to a 90-degree position, respectively.

The first casing 1 includes a torsion coil spring holding portion 8, and a spring holding portion 8a supports a torsion coil spring 11. An end face of the follower member 7 connected to the slide sheet 13 can be pushed by the protrusion 12 fastened to the first rotation shaft 9. By the force of the torsion coil spring 11, the slide sheet 13 is urged to move in a left direction in the drawing. A stopper portion 8b configured to stop movement of the slide sheet 13 in the left direction in the drawing is provided so as to protrude from a left end of the torsion coil spring holding portion 8. If the slide sheet 13 does not have any other means for stopping movement of the slide sheet 13, the slide sheet 13 will move in the left in the drawing within the first casing until the follower member 7 contacts the stopper portion 8b.

The protrusion 12 is attached to the first rotation shaft 9. When the first rotation shaft 9 revolves in a direction of arrow D in the drawing, the protrusion 12 contacts a leading end of the follower member 7, thereby causing the slide sheet 13 to slide and move.

In a state shown in FIG. 7(a), the follower member 7 contacts the stopper portion 8b of the torsion coil spring holding portion 8 and stays at standstill. The protrusion 12 stays away from the stopper portion. The slide sheet 13 holds the first group of characters, i.e., ten-key pad for phone use, in a displayed state.

When the second casing 2 is closed from the state shown in FIG. 7(a) in the first direction, the protrusion 12 contacts the follower member 7, whereby the follower member 7 and the slide sheet 13 slide.

FIG. 7(b) shows a state in which the second casing 2 is closed to 90 degrees in the first direction, whereby the protrusion 12 contacts the follower member 7. When the connection portion 3 rotates from the state shown in FIG. 7(b) in a closing direction along with the second casing 2 with respect to the first casing 1 as indicated by an arrow E, the first rotation shaft 9 integrally fixed to the connection portion 3 also rotates as indicated by the arrow E. When the first rotation shaft 9 rotates, the protrusion 12 also revolves. When revolving as indicated by the arrow E, the protrusion 12 causes the follower member 7 to move in the right direction in the drawing, i.e., in a direction of arrow F, against the force of the torsion coil spring 11.

The amount of movement of the follower member 7 is set at a half of one pitch of adjacent display windows 16a of the first casing 1. Specifically, when one pitch is defined as “P,” the follower member 7 moves to the right by “P/2,” and the slide sheet 13 to which the follower member 7 is fixed also moves to the right by “P/2.”

As described above, in the foldable mobile telephone 100 of the present invention, when the second casing 2 is closed to a predetermined angle in the first direction, the follower member 7 starts to move by the protrusion 12. Specifically, a key layout and the orientation of the display of the operation portion 51 do not change until the second casing 2 is closed in the first direction by 90 degrees. Thereafter, the second casing 2 is closed in the first direction and to an angle smaller than 90 degrees, switching of the characters begins. When the second casing 2 is completely closed, switching of the characters is completed.

The user performs operation for closing the second casing, thereby causing the slide sheet 13 provided in the first casing 1 to move, whereby a state can be switched to displaying the second group of characters, i.e., the numeral characters for use as TV channels. When the second casing 2 is closed from the state shown in FIG. 7(b), although the slide sheet 13 provided in the first casing 1 slides, the characters are hidden by the second casing 2. Therefore, the user can switch the characters while being unaware of an actual change in characters.

In the first embodiment, an example in which switching of the key layout and the orientation of the display starts when the second casing 2 is closed to 90 degrees in the first direction is described. However, the angle is not limited to 90 degrees.

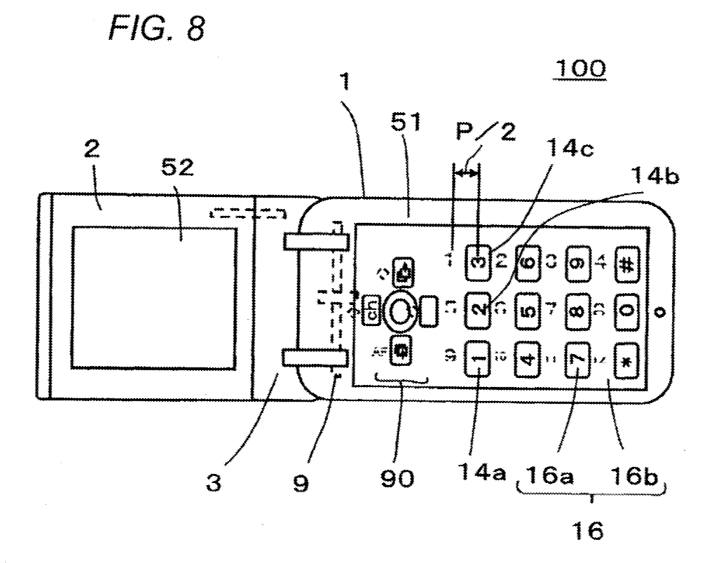

FIG. 8 shows a plan view of the foldable mobile telephone 100 in a state in which the second casing 2 is completely opened in the first direction. Since the second casing 2 is opened along with the connection portion 3, numeric characters of operation buttons are visible through the transparent display windows 16a of the first casing 1. In FIG. 8, the characters “1,” “2,” and “3” are seen and arranged in the first column from the top in the direction of the characters for phone use. The characters “4,” “5,” and “6” are arranged in the second column. The characters “7” “8,” and “9” are arranged in the third row. The characters “*,” “0,” and “#” are arranged in the fourth column. As a result, when the display portion 52 of the foldable mobile telephone 100 is set in a portrait state, the user can press the ten-key buttons as a numeric arrangement of a phone without any difficulty to select the buttons.

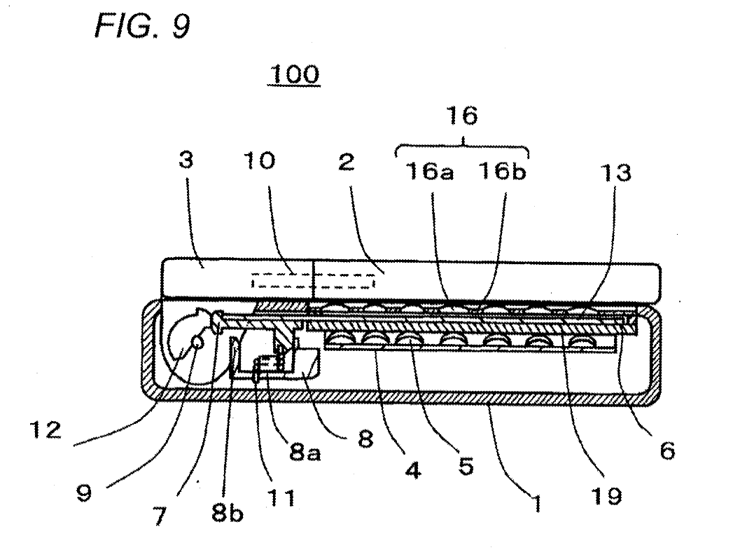

FIG. 9 shows a sate in which the second casing 2 is closed with respect to the first casing 1 along with the connection portion 3, and shows the inside of the first casing 1 in the form of a cross section as well as FIG. 7. The key circuit board 4 fixed by a support portion not shown is placed in the first casing 1, and the diaphragms 5 are placed on the key circuit board 4 such that the number thereof is smaller than the number of the characters and numeric characters printed on the slide sheet 13. The pusher sheet 19 is fixed onto the diaphragms 5. In the drawing, the sectional shapes of the frame portion 6 and the pusher sheet 19 are emphasized so as to be clearly shown. However, the actual overall thickness is thin. When the pusher sheet 19 is pressed from above, the pusher sheet 19 bends, and a center of the diaphragm 5 located immediately below a pressed position is dented. Accordingly, the key entry is implemented.

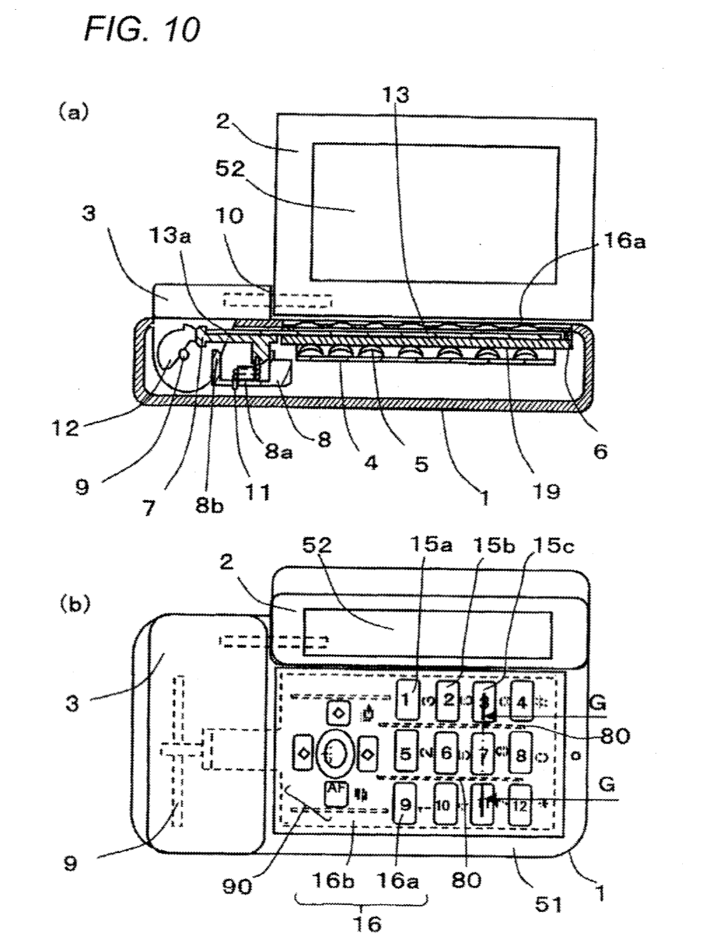

FIG. 10(a) shows a state in which the second casing 2 is opened in the second direction. The first casing 1 is shown in the form of a cross section. The connection portion 3 remains closed with respect to the first casing 1, but the second casing 2 rotates around the second rotation shaft 10, such that the display portion 52 becomes visible. Since the connection portion 3 remains closed with respect to the first casing 1, the first rotation shaft 9 does not rotate. Specifically, the protrusion 12 does not revolve, and a position of the slide sheet 13 is the same position as that when the second casing 2 shown in FIG. 9 is closed.

FIG. 10(b) shows a plan view of the foldable mobile telephone 100 when the second casing 2 is opened in the second direction. Since the second casing 2 remains open, the numeric characters on the operation buttons are visible through the display window 16a of the first casing 1. In FIG. 10(b), the numeric characters “1” to “12” for television channels are seen and arranged in sequence from top with respect to the orientation of characters, i.e., namely, the characters “1,” “2,” “3,” and “4” are arranged in the first column. The characters “5,” “6,” “7,” and “8” are arranged in the second column, and the characters “9,” “10,” “11,” and “12” are arranged in the third column.

When the display portion 52 of the foldable mobile telephone 100 is set in a landscape state in order to view a TV broadcast, the user can press any one of channel numbers “1” to “12” without any difficulty to select the buttons. Similar the ten-key buttons, a display showing the functions of the four-way directional pad is also switched to an orientation conforming to an opening direction of the second casing 2.

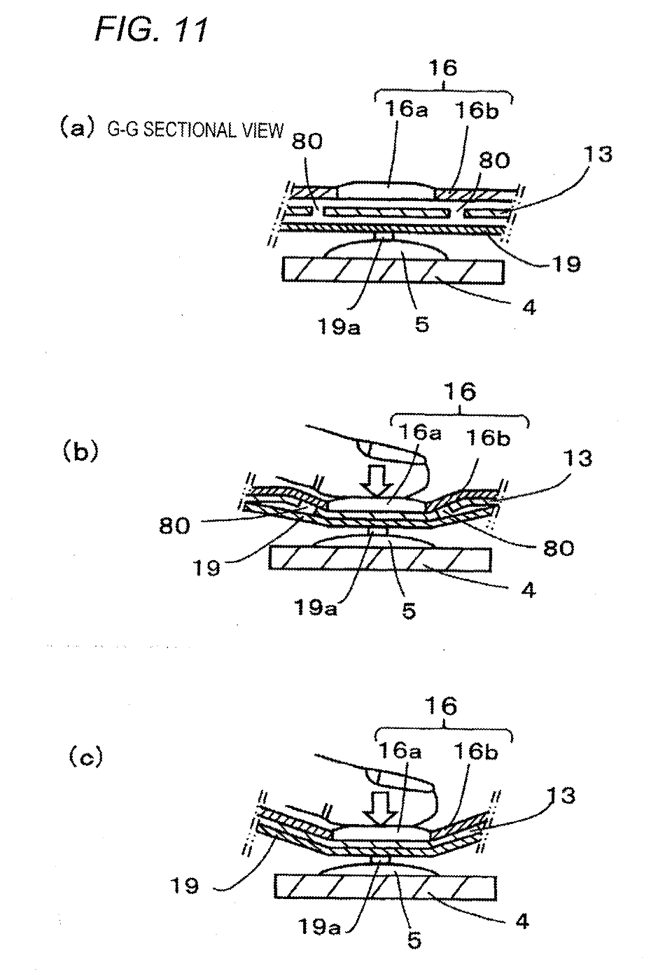

With reference to FIG. 11, the following are description for explaining advantages obtained by forming the slits 80 in the region of the slide sheet 13 where the functions of the respective buttons are not printed, such that the resistance force on pressing the ten-key, etc., becomes smaller, and the ten-key, etc., can be pressed without fail and easily. FIG. 11(a) is a cross sectional view taken along a line G-G shown in FIG. 10(b) and shows a partial sectional view of the ten-key region of the operation portion 51 of the present invention. FIG. 11(b) shows a state in which the display window 16a of the key top sheet 16 in the ten-key region of the operation portion 51 of the present invention is pressed with a finger. FIG. 11(c) shows, for comparison purpose, that the ten-key region is pressed with a finger when a related art slide sheet not having slits is used.

As shown in FIG. 11(a), the diaphragms 5 are disposed on the key circuit board 4. Plugs 19a of the pusher sheet 19 contact the respective diaphragms 5. The slide sheet 13 having the slits 80 is disposed above the plugs 19a of the pusher sheet 19. The key top sheet 16 is disposed above the slide sheet 13.

In the present invention, the slits 80 are formed in the slide sheet 13 as described above. Therefore, when the display window 16a of the key top sheet 16 is pressed with the finger as shown In FIG. 11(b), an entire surface of the slide sheet 13 is not deflected, but a portion of the surface between the slits or a portion of the surface corresponding to a narrowly elongated strip-shaped surface defined between the slit and an edge of the slide sheet is pressed. As a result, the force for deflecting the slide sheet 13 can be reduced, and only an area of the sheet desired to be depressed can be easily deformed. A press can be performed without fail.

If slits are not formed in the slide sheet 13, when any of the ten-key buttons of the operation portion 51 is pressed as shown in FIG. 11(c), the entirety of three sheets, i.e., the key top sheet 16, the slide sheet 13 and the pusher sheet 19, are deformed, so that high resistance force occurs by pressing action. In particular, since a plastic sheet that is not easily bent by sliding action and that exhibits comparatively high rigidity is used for the slide sheet 13, the slide sheet 13 is not likely to stretch and deform. In order to deform the entirety of the slide sheet 13, pressing force of a given value or more is required. For this reason, when any of the ten-key buttons is lightly touched, a corresponding diaphragm is not sufficiently deformed even when the user has felt resistance force. A failure to detect pressing of the ten digit key may also take place.

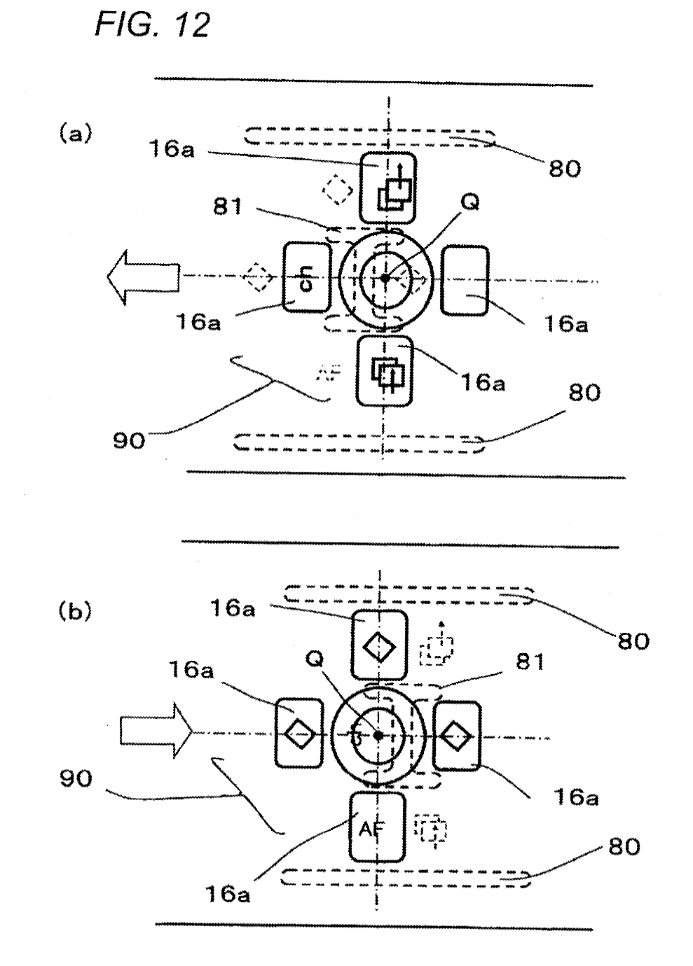

A configuration including the substantially H-shaped slit 81 formed in the center of the four-way directional pad 90 of the slide sheet 13 and an advantage thereof are now described. FIG. 12 is an enlarged view of the region corresponding to the four-way directional pad, etc. when the key top sheet 16 overlaid on the slide sheet 13 is viewed from above. The substantially H-shaped slit 81 is formed in the slide sheet 13. The substantially H-shaped slit 81 includes a first slit and a second slit that are formed along a direction of movement of the slide and a third slit substantially perpendicular to the first slit and the second slit, so as to connect the first slit to the second slit by the third slit.

An explanation is given by reference to FIG. 12(a). FIG. 12(a) shows, by a solid line, printed areas (the first group of characters) overlapping respective display windows located around the four-way directional pad 90 when the second casing 2 is opened in the first direction as shown in FIG. 8. At this time, the slide sheet 13 has moved to the left direction in FIG. 12(a).

A positional relationship between a center Q serving as a center of the four-way directional pad and the slide sheet 13 is now described. In FIG. 12(a), the substantially H-shaped slit 81 formed in the slide sheet 13 is situated on the left side of the center Q. Therefore, when the center key surrounded by the four-way directional pad is pressed, a right-side portion of the substantially H-shaped slit 81 becomes partially deformed, whereby the center key surrounded by the four-way directional pad can be reliably pressed with a smaller sense of resistance (to a deformation).

FIG. 12(b) shows, by a solid line, printed areas (the second group of characters) overlapping respective display windows located around the four-way directional pad 90 when the second casing 2 is opened in the second direction. At this time, the slide sheet 13 has already moved to the right in FIG. 12(b). In FIG. 12(b), the substantially H-shaped slit 81 is situated on the right side of the center Q. When the center key situated at the center of the four-way directional pad is pressed, a left-side portion of the substantially H-shaped slit 81 (particularly the third slit) becomes partially deformed, whereby the center key can be reliably pressed with a smaller sense of resistance (to a deformation).

The right side and the left side, each of which is pressed through the center of the four-way directional pad, have symmetry. Hence, a sense of resistance that is felt when the center of the four-way directional pad 90 is pressed is substantially same. For this reason, there is provided an advantage of providing no feeling of strangeness even when the position of the slide sheet 13 is switched.

Further, even when the slide sheet 13 is pressed through the substantially H-shaped slit 81 formed therein (particularly the first slit and the second slit) by pressing the four-way directional pad located around the center key, a sense of resistance becomes smaller when compared with the case where no slit is provided and where the slide sheet 13 is deformed by pressing the entire surface, so that pressing can be performed without fail.

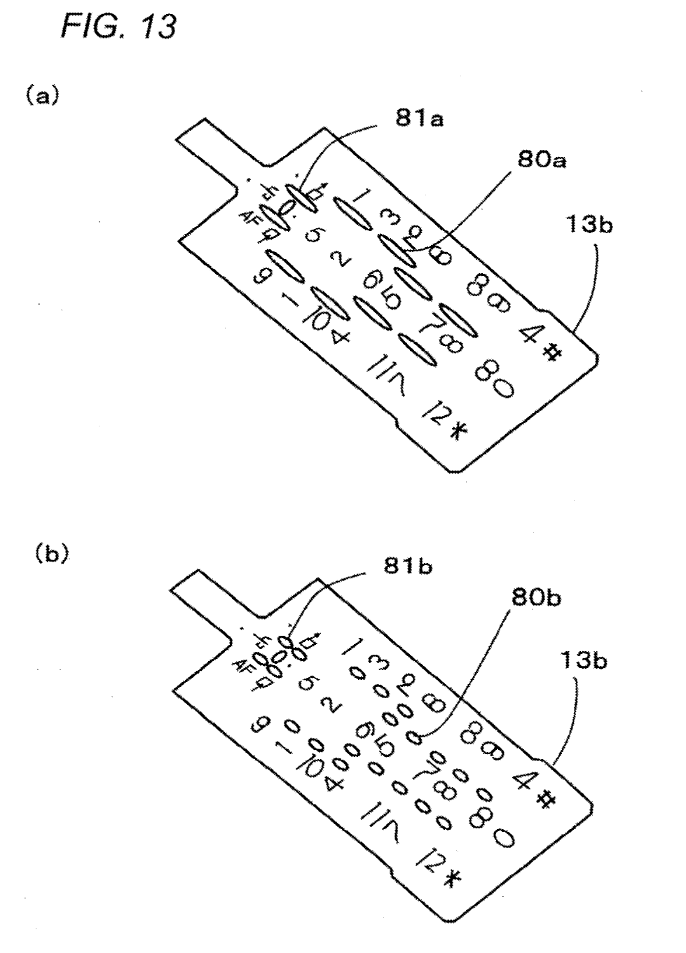

The shape of the slits 80 formed in the region of the slide sheet 13 where the functions of the respective buttons are not printed is described as narrowly elongated square holes in the above descriptions including FIGS. 3 and 4. However, a series of narrowly elongated oval holes may be formed in proximity to each other as shown in FIG. 13(a). Alternatively, the substantially H-shaped slit may also be formed in a shape in which narrowly elongated oval holes are formed in proximity to each other so as to form a substantially H-shaped geometry.

The embodiment is not limited to the slits, and may be any hole so long as the key sheet becomes deformed. The shape is not limited to the slits of the present embodiment. For instance, a plurality of small circular holes rather than the slits may be formed in a line along the direction of movement of the key sheet. Specifically, the holes may be formed so as to assume a shape including small elongated, rice-shaped holes arranged in a line as shown in FIG. 13(b). Moreover, the holes may also be formed so as to assume a shape in which small circular holes rather than the elongated holes are arranged in a line as shown in FIG. 14.

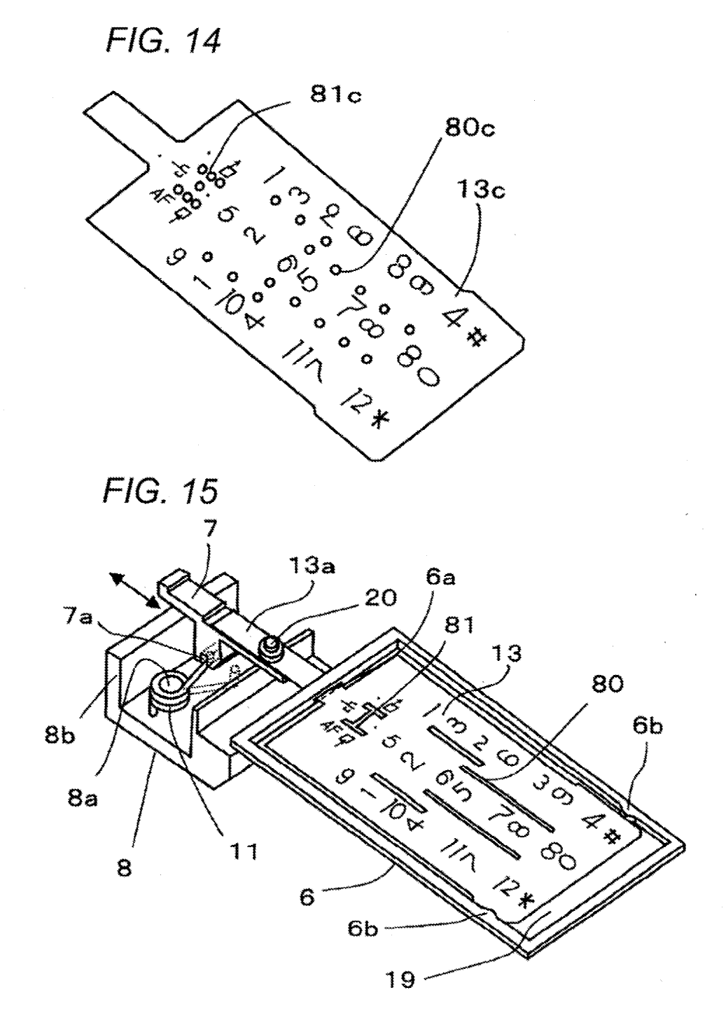

FIG. 15 is a perspective view, in which the frame portion 6 and the pusher sheet 19 are assembled, the slide sheet 13 is placed on the pusher sheet 19, the follower mounting portion 13a is caused to pass through the space between the step portion 6a of the frame portion and the pusher sheet 19, and follower member 7 is fixed to the follower mounting portion 13a and screw-engaged with the torsion coil spring 11.

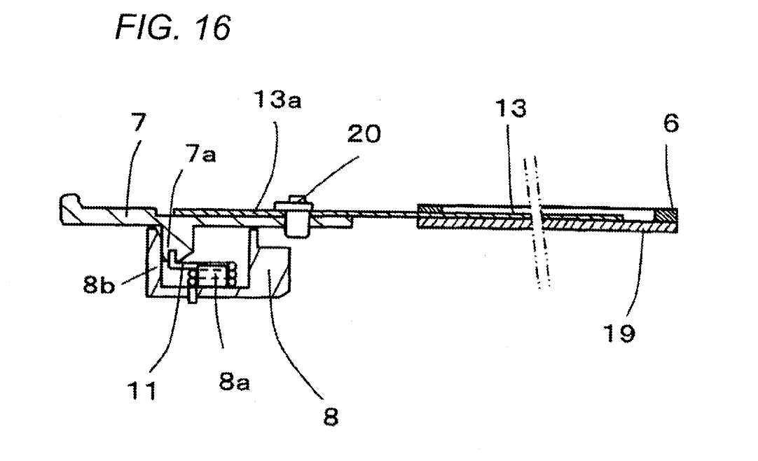

FIG. 16 shows a cross section of FIG. 15. As shown in FIG. 16, a groove 7a is formed in a lower portion of the follower member 7, and a leading end of the torsion coil spring 11 is engaged with the groove 7a. The torsion coil spring 11 is attached to the torsion coil spring holding portion 8. The torsion coil spring holding portion 8 includes the holding portion 8a and the stopper 8b which exhibit same functions as those shown in FIG. 7.

The leading end of the torsion coil spring 11 moves along a locus shaped in a circular arc but slides in a direction of the groove 7a formed in the lower portion of the follower member 7. Although detailed explanations are not provided in the above description, the present invention includes a guide pin 20 serving as means for fixing the slide sheet 13 to the follower member 7, which is fitted into the follower member 7 from above the follower mounting portion 13a of the slide sheet 13. The guide pin 20 collides with a guide groove not shown provided in the first casing 1 to extend in a sliding direction of the slide sheet, thereby regulating a sliding action of the slide sheet 13 so as not to move in a direction perpendicular to the sliding direction when the slide sheet 13 slides.

As described above, the sliding action of the slide sheet 13 is regulated by means of the guide pin 20 and the guide groove not shown provided in the first casing 1 in the sliding direction thereof. Hence, the slide sheet 13 moves in only its sliding direction. Consequently, the slide sheet 13 performs stable sliding action.

In FIG. 15, the slits 80 of the slide sheet 13 are not made in the sequence of characters (“*,” “0,” and “#”) on the end portion of the slide sheet 13 opposite to a side connected to the follower member 7. Since the end face of the slide sheet is likely to become deformed, a sense of operation is not lost even when the slits are not provided. Further, since the positioning of the slide sheet is determined at the end of the slide sheet opposite to its end facing the follower member 7, the rigidity of the slide sheet is assured by omission of slits, and positional accuracy of the slide sheet can be enhanced.

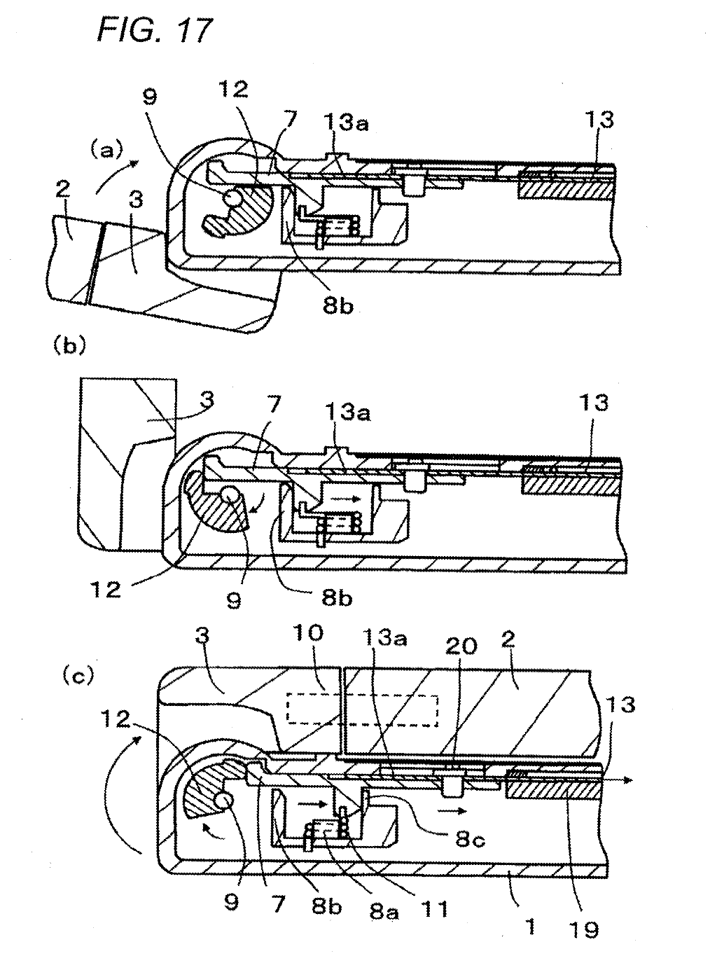

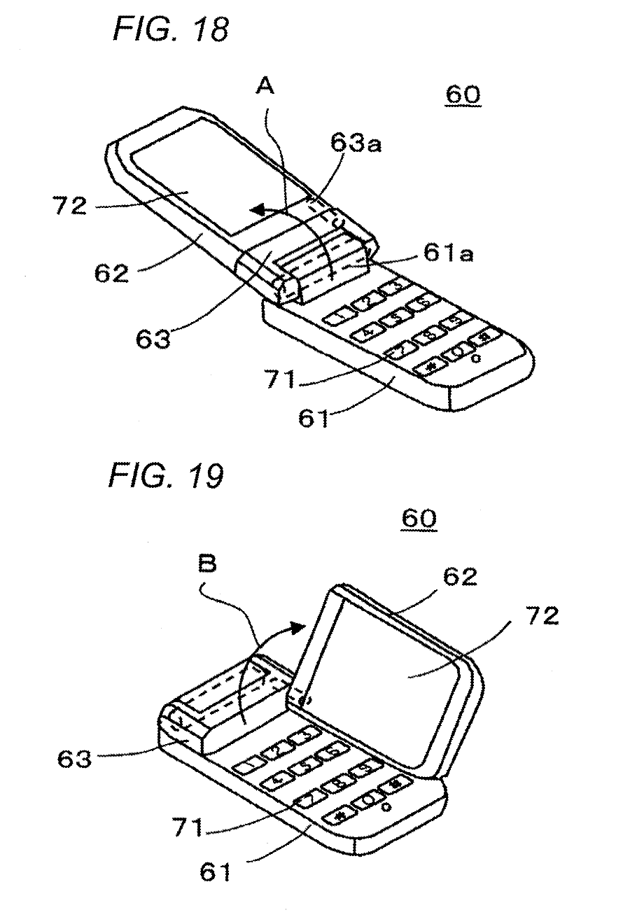

FIGS. 17(a) to 17(c) show details of the cross section of the slide sheet 13 when the second casing 2 shown in FIG. 7 and the connection portion 3 are opened and closed with respect to the first casing 1.

FIG. 17(a) is a cross sectional view of the slide sheet when the second casing 2 and the connection portion 3 are completely opened. FIG. 17(b) is a cross sectional view of the slide sheet when the second casing 2 and the connection portion 3 are opened to 90 degrees. FIG. 17(c) is a partial sectional view of the slide sheet when the second casing 2 along with the connection portion 3 are closed with respect to the first casing 1.

In the first embodiment, the protrusion 12 fixed to the first rotation shaft 9 revolves in association with the rotation action of the first rotation shaft, thereby pushing the follower member 7. The slide sheet 13 connected to the follower member 7 slides, thereby switching a group of prints overlapping the display windows of the key top sheet according to an open state or closed state. Switching of a display is thus implemented.

Specifically, the slide sheet 13 is caused to slide in association with rotation action of the first rotation shaft 9, thereby mechanically switching specifics to be displayed on the operation portion and an orientation of the display. Even when the power supply of the portable terminal apparatus is not turned on, the specifics to be displayed on the operation portion and an orientation of the display can be switched without fail.

The layout of the protrusion is not limited to that described in connection with the present embodiment, and another structure may also be employed so long as rotation action of the first rotation shaft 9 is transmitted in association with the protrusion 12 in the structure. For example, another shaft may also be interposed between the first rotation shaft 9 and the shaft of the protrusion 12, thereby allowing the first rotation shaft 9 and the protrusion 12 to operate synchronously. Thereby, the position of the shaft of the protrusion can arbitrarily be set.

The mobile telephone having television broadcast receiving means is described as one type of the portable terminal apparatus device. However, in a mobile telephone with a game function, switching may also be made to a button layout for gaming purpose so that the phone can be used as a game machine when opened in the second direction. In addition, the characters that are displayed in two different directions may also be arranged in a staggered configuration.

Example arrangements of the characters displayed when the second casing is opened in the second direction with respect to the first casing include a first column of “1,” “2,” “3,” “4,” a second column of “5,” “6,” “7,” “8,” and a third column of “9,” “10,” “11,” “12.” However, in order to perform entry of a mail without a feeling of strangeness, a first column of “1,” “2,” “3,” a second row of “4,” “5,” “6,” and a third row of “7,” “8,” “9” may be adopted from above with respect to the orientation of the characters.

In the present embodiment, accuracy is assured by bringing the slide sheet 13 into contact with the stopper 8b as a reference for assuring positional accuracy of the slide sheet. However, there may also be adopted a configuration in which positional accuracy is assured by bringing the slide sheet 13 into contact with an inner end face of the frame portion 6.

Although detailed descriptions are omitted for FIGS. 3 and 4, a protrusion 6b is formed inside of the frame portion 6 in its shorter direction, and a protrusion 13b is formed on both ends of the slide sheet 13 in its shorter direction. These protrusions are for positionally regulating the slide sheet in a horizontal direction by bringing the protrusions 6b of the frame portion in contact with the respective protrusions 13b of the slide sheet when the slide sheet slides. Since the slide sheet is positionally regulated by a small contact area between the protrusions (point contact), influence of positional regulation on the sliding resistance of the slide sheet becomes smaller. Further, since the dimensional accuracy of the slide sheet and the frame becomes easy to assure, positional accuracy of the slide sheet is enhanced. Therefore, such a guide is useful for obtaining positional accuracy of the slide sheet by the frame.

Although the present invention has been described in detail and with reference to the specific embodiments, it is a matter of course that various changes or modifications may be made without departing the spirit and scope of the invention.

The present patent application is based on Japanese Patent Application No. 2008-145315 filed on Jun. 3, 2008, the entire subject matter of which is incorporated herein by reference.

### INDUSTRIAL APPLICABILITY

The present invention can be applied not only to a foldable mobile telephone but also to a foldable portable terminal apparatus that includes a connection portion containing two rotation shafts so as to allow the portable terminal apparatus to open and close in a first direction and a second direction, e.g., a game machine that is used while a display screen is switched between a landscape orientation and a portrait orientation and a PDA having a television broadcast receiving function.

1. A foldable portable terminal apparatus comprising:
a first casing including an operation portion, and a second casing including a display portion, which are connected through a connection portion so as to allow the second casing to open and close with respect to the first casing in a first direction and a second direction different from the first direction,
wherein said portable terminal apparatus comprises a slide sheet printed with a character or symbol for operation purpose, and
wherein the slide sheet slides in association with opening and closing actions in the first direction and has a slit formed along a sliding direction thereof.

2. The foldable portable terminal apparatus according to claim 1,
wherein the slit is formed in a region between the printed characters or symbols for operation purpose.

3. The foldable portable terminal apparatus according to claim 1,
wherein the slit is formed in a region where the character or symbol for operation purpose is not printed.

4. A foldable portable terminal apparatus comprising:
a first casing including an operation portion, and a second casing including a display portion, which are connected through a connection portion so as to allow the second casing to open and close with respect to the first casing in a first direction and a second direction different from the first direction,
wherein said portable terminal apparatus comprises a slide sheet printed with a character or symbol for operation purpose, and
wherein the slide sheet slides in association with opening and closing actions in the first direction and has a slit formed along the first direction.

5. The foldable portable terminal apparatus according to claim 4,
wherein the slit is formed in a region between the printed characters or symbols for operation purpose.

6. The foldable portable terminal apparatus according to claim 4,
wherein the slit is formed in a region where the character or symbol for operation purpose is not printed.

7. The foldable portable terminal according to claim 1,
wherein the slide sheet comprises an attaching portion formed on one end of the slide sheet, and the slit is not formed on an end opposite to the attaching portion.

8. The foldable portable terminal apparatus according to claim 1,
wherein the slide sheet is printed with a character or symbol for operating a plurality of direction buttons, and
wherein the slide sheet has first and second slits formed along a sliding direction thereof and a third slit connecting the first slit and the second slit.

9. The foldable portable terminal apparatus according to claim 4,
wherein the slide sheet is printed with a character or symbol for operating a plurality of direction buttons, and
wherein the slide sheet has first and second slits formed along the first direction and a third slit connecting the first slit and the second slit.

10. The foldable portable terminal apparatus according to claim 8,
wherein the first slit, the second slit and the third slit form a substantially H-shaped slit.

11. A slide sheet used in an operation portion of a foldable portable terminal apparatus that comprises a first casing including the operation portion, and a second casing including a display portion, which are connected through a connection portion so as to allow the second casing to open and close with respect to the first casing in a first direction and a second direction different from the first direction,
wherein said slide sheet has a print of character or symbol for operation purpose, slides in association With opening and closing actions in the first direction, and has a slit formed along a sliding direction thereof.

12. The slide sheet according to claim 11,
wherein the slit is formed in a region between the prints of characters or symbols for operation purpose.

13. The slide sheet
wherein the slit is formed in a region where the character or symbol for operation purpose is not printed.

14. A slide sheet used in an operation portion of a foldable portable terminal apparatus that comprises a first casing including the operation portion, and a second casing including a display portion, which are connected through a connection portion so as to allow the second casing to open and close with respect to the first casing in a first direction and a second direction different from the first direction,
wherein said slide sheet has a print of a character or symbol for operation purpose, slides in association with opening and closing actions in the first direction and has a slit formed along the first direction.

15. The slide sheet according to claim 14,
wherein the slit is formed in a region between the prints of characters or symbols for operation purpose.

16. The slide sheet according to claim 14,
wherein the slit is formed in a region where the character or symbol for operation purpose is not printed.

17. The slide sheet according to claim 11, comprising:
an attaching portion formed on one end of the slide sheet,
wherein the slit is not formed on an end opposite to the attaching portion.

18. The slide sheet according to claim 11,
wherein said slide sheet has a print of character or symbol for operating the plurality of direction buttons, and has first and second slits formed along a sliding direction thereof and a third slit connecting the first slit to the second slit.

19. The slide sheet according to claim 14,
wherein said slide sheet has a print of a character or symbols for operating the plurality of direction buttons, and has first and second slits formed along the first direction and a third slit connecting the first slit to the second slit.

20. The slide sheet according to claim 18,
wherein the first slit, the second slit and the third slit form a substantially H-shaped slit.

21. A foldable portable terminal apparatus comprising:
a first casing including an operation portion and a second casing including a display portion, which are connected through a connection portion so as to allow the second casing to open and close with respect to the first casing in a first direction and a second direction different from the first direction,
wherein said portable terminal apparatus comprises a slide sheet printed with a character or symbol for operation purpose, and
wherein the slide sheet slides in association with opening and closing actions in the first direction and comprises a protrusion in a direction perpendicular to a sliding direction such that when sliding, the slide sheet is positionally regulated by the protrusion in the direction perpendicular to the sliding direction.

22. A foldable portable terminal apparatus comprising:
a first casing including an operation portion and a second casing including a display portion, which are connected through a connection portion so as to allow the second casing to open and close with respect to the first casing in a first direction and a second direction different from the first direction,
wherein said portable terminal apparatus comprises a slide sheet printed with a character or symbol for operation purpose, and
wherein the slide sheet slides in the first direction in association with opening and closing actions in the first direction and comprises a protrusion in the second direction such that when sliding, the slide sheet is positionally regulated by the protrusion in the second direction.

23. The foldable portable terminal apparatus according to claim 21,
wherein the protrusion is formed on a side of the slide sheet extending along the sliding direction.

24. The foldable portable terminal apparatus according to claim 22,
wherein the protrusion is formed on a side of the slide sheet extending along the first direction.

25. The foldable portable terminal apparatus according to claim 23,
wherein the slide sheet comprises an attaching portion formed on one end of the slide sheet, and
wherein the protrusion is formed on a far side of the side of the slide sheet extending along the sliding direction from the attaching portion.

26. A slide sheet used in an operation portion of a foldable portable terminal apparatus that comprises a first casing including the operation portion and a second casing including a display portion, which are connected through a connection portion so as to allow the second casing to open and close with respect to the first casing in a first direction and a second direction different from the first direction,
wherein said slide sheet has a print of a character or symbol for operation purpose, slides in association with opening and closing actions in the first direction, and comprises a protrusion in a direction perpendicular to a sliding direction thereof such that when sliding, the slide sheet is positionally regulated by the protrusion in the direction perpendicular to the sliding direction.

27. A slide sheet is used in an operation portion of a foldable portable terminal apparatus that comprises a first casing including the operation portion and a second casing including a display portion, which are connected through a connection portion so as to allow the second casing to open and close with respect to the first casing in a first direction and a second direction different from the first direction,
wherein said slide sheet has a print of a character or symbol for operation purpose, slides in the first direction in association with opening and closing actions in the first direction, and comprises a protrusion in the second direction such that when sliding, the slide sheet is positionally regulated by the protrusion in the second direction.

28. The slide sheet according to claim 26,
wherein the protrusion is formed on a side of the slide sheet extending along the sliding direction.

29. The slide sheet according to claim 27,
wherein the protrusion is formed on a side of the slide sheet extending along the first direction.

30. The slide sheet according to claim 28, comprising:
an attaching portion formed on one end of the slide sheet,
wherein the protrusion is formed on a far side of the side of the slide sheet extending along the sliding direction from the attaching portion.

31. The foldable portable terminal according to claim 4,
wherein the slide sheet comprises an attaching portion formed on one end of the slide sheet, and the slit is not formed on an end opposite to the attaching portion.

32. The foldable portable terminal apparatus according to claim 9,
wherein the first slit, the second slit and the third slit form a substantially H-shaped slit.

33. The slide sheet according to claim 14, comprising:
an attaching portion formed on one end of the slide sheet,
wherein the slit is not formed on an end opposite to the attaching portion.

34. The slide sheet according to claim 19,
wherein the first slit, the second slit and the third slit form a substantially H-shaped slit.
